(19) United States
(12) Patent Application Publication
(10) Pub. No.: US 2026/0206536 A1
(43) Pub. Date: Jul. 16, 2026

(54) PROCESS CONNECTION DEVICE IN SUBSTRATE MANUFACTURING PROCESS AND OPERATING METHOD THEREOF

(71) Applicant: S.E.A Co., Ltd., Gyeongsangbuk-do (KR)

(72) Inventor: Jaeho Shin, Gumi-si (KR)

(21) Appl. No.: 19/228,525

(22) Filed: Jun. 4, 2025

(30) Foreign Application Priority Data
Jan. 14, 2025 (KR) 10-2025-0005520

(51) Int. Cl. H01L 21/677

(52) U.S. Cl. CPC H10P 72/3411

(57) ABSTRACT

A process connection device in a substrate manufacturing process and an operating method thereof are disclosed. A process connection device in a substrate manufacturing process according to an embodiment may comprise an automation unit configured to sequentially stack horizontally positioned substrates loaded in a horizontal direction onto a horizontally positioned carrier, convert the horizontally positioned carrier into a vertical position, insert the vertically positioned carrier into a vertical process, convert the vertically positioned carrier discharged from the vertical process into a horizontal position, and sequentially discharge the horizontally positioned substrates from the horizontally positioned carrier and insert them into a horizontal process.

### CROSS-REFERENCE TO RELATED APPLICATION

This application claims the benefit of priority under 35 U.S.C. § 119 to Korean Patent Application No. 10-2025-0005520 filed on Jan. 14, 2025, in the Korean Intellectual Property Office (KIPO), the entire contents of which are incorporated herein by reference.

### BACKGROUND

### 1. Field

The following embodiments relate to a device for connecting a vertical process in which a substrate is processed in a vertical position and a horizontal process in which a substrate is processed in a horizontal position and an operating method thereof.

2. Description of Related Art

For products like substrates, a substrate processing device is used to perform surface treatment processes, such as circuit formation, plating, and the like.

The substrate processing device may include a chemical processing device that performs wet processing on the substrate using various types of chemicals (e.g., plating solutions, cleaning solutions, and other treatment solutions) depending on whether it employs a dip type or spray type method and a cleaning and drying device to remove residual chemicals and moisture from the surface of the chemically processed substrate.

Recently, to improve substrate processing efficiency, the substrate processing device has adopted a method in which multiple substrates are processed in a carrier standard stacked in vertical position, in performing chemical processing.

The technology related to such vertical continuous plating device is disclosed in Korean Registered Patent Publication No. 10-2539090 (registration date: May 26, 2023).

Chemically processed substrates typically undergo a separate drying process to improve the processing speed for substrate process. In this drying process, the substrates are placed on a carrier and dried using an oven or high-temperature hot air.

However, as the substrates are processed in a carrier standard in which the substrates are stacked vertically, cleaning and drying of the substrates are not performed efficiently. This can result in chemical residues, stains, or incomplete drying on the substrate surfaces. To address this issue, there has been a growing need for individual drying of each substrate. Conventionally, to resolve this issue, labor was deployed to manually separate each substrate from the carrier and insert them individually into a drying device. However, this approach lowered productivity and caused problems such as stains or damage due to manual handling, or delays during the separation process, which in turn led to stains from natural drying on some substrates.

Therefore, there is a need to propose a technology that can solve the aforementioned issues.

### SUMMARY

Embodiments propose a process connection device in a substrate manufacturing process and an operating method thereof, which automate integration of a vertical process—where substrates are processed in a carrier standard with vertically stacked substrates—and a horizontal process—where cleaning and drying are performed in a substrate standard on each substrate individually in a horizontal position—to enhance productivity and quality stability in chemical treatment, and cleaning and drying process of the substrate.

In particular, embodiments propose a process connection device and an operating method in a substrate manufacturing process that efficiently connects the vertical process and the horizontal process, which are implemented at different locations, in order to minimize equipment space and maximize space efficiency.

However, the technical problems intended to be solved by the present invention are not limited to the aforementioned problems, and various modifications may be made without departing from the spirit and scope of the present invention.

According to one embodiment, a process connection device in a substrate manufacturing process may comprise an automation unit configured to sequentially stack horizontally positioned substrates loaded in a horizontal direction onto a horizontally positioned carrier, convert the horizontally positioned carrier into a vertical position, insert the vertically positioned carrier into a vertical process, convert the vertically positioned carrier discharged from the vertical process into a horizontal position, and sequentially discharge the horizontally positioned substrates from the horizontally positioned carrier and insert them into a horizontal process.

According to an aspect, the automation unit may be configured to integrally implement a carrier stacking function of substrates, a carrier position conversion function, a movement function between a location of the vertical process related equipment and a location of the horizontal process related equipment, and a substrate discharging function from the carrier.

According to another aspect, the automation unit may be configured to connect the vertical process and the horizontal process, which are implemented at different locations, through the movement function.

According to another aspect, the vertical process may include a carrier standard substrate process, and the horizontal process may include a substrate standard substrate process.

According to another aspect, the automation unit may be configured to move from a location of the vertical process related equipment to a location of the horizontal process related equipment and then convert the vertically positioned carrier into a horizontal position.

According to another aspect, the vertical process related equipment and the horizontal process related equipment may be provided at different locations in either the same direction or opposing directions.

According to another aspect, the automation unit may be configured to lower or raise the horizontally positioned carrier where the substrates are not stacked while sequentially stacking the horizontally positioned substrates, and raise or lower the horizontally positioned carrier where the substrates are stacked while sequentially discharging the horizontally positioned substrates.

According to another aspect, the automation unit may be configured to adjust the rising or lowering height of the horizontally positioned carrier according to a thickness of each substrate.

According to another aspect, the automation unit may be configured to transfer the carrier with stacked substrates to a buffer for temporary storage.

According to one embodiment, an operating method of a process connection device in a substrate manufacturing process may comprise sequentially stacking horizontally positioned substrates loaded in a horizontal direction onto a horizontal positioned carrier, by an automation unit included in the process connection device; converting the horizontally positioned carrier into a vertical position, by the automation unit; inserting the vertically positioned carrier into a vertical process, by the automation unit; converting the vertically positioned carrier discharged from the vertical process into a horizontal position, by the automation unit; and sequentially discharging the horizontally positioned substrates from the horizontally positioned carrier and inserting them into a horizontal process, by the automation unit.

According to an aspect, the converting the vertically positioned carrier discharged from the vertical process into a horizontal position may be moving the automation unit from a location of the vertical process related equipment to a location of the horizontal process related equipment, and then converting the vertically positioned carrier to a horizontal position.

According to another aspect, the vertical process and the horizontal process, which are implemented at different locations, may be connected to each other through a movement of the automation unit.

According to another aspect, the vertical process may include a carrier standard substrate process, and the horizontal process may include a substrate standard substrate process.

According to another aspect, the sequentially stacking horizontally positioned substrates loaded in a horizontal direction onto a horizontal positioned carrier may comprise lowering or raising the horizontally positioned carrier where the substrates are not stacked while sequentially stacking the horizontally positioned substrates, and the sequentially discharging the horizontally positioned substrates from the horizontal positioned carrier and inserting them into a horizontal process may comprise raising or lowering the horizontally positioned carrier where the substrates are stacked while sequentially discharging the horizontally positioned substrates.

According to another aspect, the operating method of a process connection device in a substrate manufacturing process may further comprise transferring the carrier with stacked substrates to a buffer for temporary storage, by the automation unit.

Embodiments may achieve technical effects of enhancing productivity and quality stability in chemical treatment, cleaning and drying process of the substrate by proposing a process connection device in a substrate manufacturing process and an operating method thereof, which automate integration of a vertical process—where substrates are processed in a carrier standard with vertically stacked substrates—and a horizontal process—where cleaning and drying are performed in a substrate standard on each substrate individually in a horizontal position.

Particularly, embodiments may achieve technical effects of minimizing equipment space and maximizing space efficiency by proposing a process connection device and an operating method in a substrate manufacturing process that efficiently connects the vertical process and the horizontal process, which are implemented at different locations.

However, the effects of the present invention are not limited to those described above, and various other advantages may be realized without departing from the spirit and scope of the present invention.

### BRIEF DESCRIPTION OF THE DRAWINGS

FIG. 1 is a planar drawing illustrating a process connection device in a substrate manufacturing process according to an embodiment;

FIG. 2 is a side view illustrating a process connection device in a substrate manufacturing process according to an embodiment;

FIG. 3 is a front view illustrating a process connection device in a substrate manufacturing process according to an embodiment;

FIG. 4 is a side view for describing an automation unit according to an embodiment; and

FIG. 5 is a flow chart illustrating an operating method of a process connection device in a substrate manufacturing process shown in FIGS. 1 to 4.

### DETAILED DESCRIPTION

Hereinafter, embodiments of the present invention will be described in detail with reference to the accompanying drawings, so that those skilled in the art to which the present invention pertains can easily implement the invention. The description of the present invention is merely illustrative of structural and functional features of specific embodiments and should not be construed as limiting the scope of the invention to the embodiments described herein.

In other words, the present invention is not limited to the specific embodiments described and may be modified and implemented in various different forms. Therefore, the scope of the present invention should be understood to include equivalents capable of realizing the technical idea of the invention.

Meanwhile, the meanings of the terms used in the present invention should be interpreted as follows.

The terms such as “first,” “second,” and the like are used to distinguish one component from another component and should not be construed as limiting the scope of the invention. For example, a first component may be referred to as a second component, and similarly, a second component may be referred to as a first component.

When a component is described as being “connected to” another component, it should be understood that the connection may be either direct or via another intervening component. On the other hand, when a component is described as being “directly connected to” another component, it should be understood that there are no intervening components between them. Meanwhile, other expressions describing relationships between components, such as “between” and “directly between,” or “adjacent to” and “directly adjacent to,” should be interpreted in the same manner.

Singular expressions should be understood to include plural forms unless the context clearly dictates otherwise. Furthermore, the terms “comprise,” “include,” or “have,” and variations thereof, are intended to specify the presence of stated features, numbers, steps, operations, elements, components, or combinations thereof, but do not preclude the presence or addition of one or more other features, numbers, steps, operations, elements, components, or combinations thereof.

The identification symbols used in each step (e.g., a, b, c, etc.) are provided for convenience of explanation only and do not represent the order of the steps. Unless explicitly stated otherwise, the steps may be performed in a different order than presented, and may be performed substantially simultaneously, or even in reverse order.

Unless otherwise defined, all terms used herein should be interpreted in accordance with their ordinary and customary meanings as understood by those skilled in the art. Terms that are generally defined in commonly used dictionaries should be interpreted as having meanings consistent with the relevant technical field and should not be interpreted in an overly idealized or overly formal sense unless explicitly defined otherwise in the present invention.

It should also be noted that the drawings are schematic and not necessarily drawn to scale. The relative dimensions and ratios of components illustrated in the drawings may be exaggerated or reduced for clarity and convenience, and any dimensions are merely illustrative and not intended to be limiting. The same reference numerals used in two or more drawings refer to similar or identical elements, features, or components.

The embodiments described herein represent exemplary implementations of the present invention. As such, various modifications of the illustrated configurations may be anticipated. Therefore, the embodiments should not be limited to the particular shapes shown in the figures, and variations due to manufacturing processes or design modifications are also included.

Hereinafter, with reference to the attached drawings, it will be described a process connection device in a substrate manufacturing process and an operating method thereof, which automate integration of a vertical process—where substrates are processed in a carrier standard with vertically stacked substrates—and a horizontal process—where cleaning and drying are performed in a substrate standard on each substrate individually in a horizontal position—to enhance productivity and quality stability in chemical treatment and cleaning and drying process of the substrate.

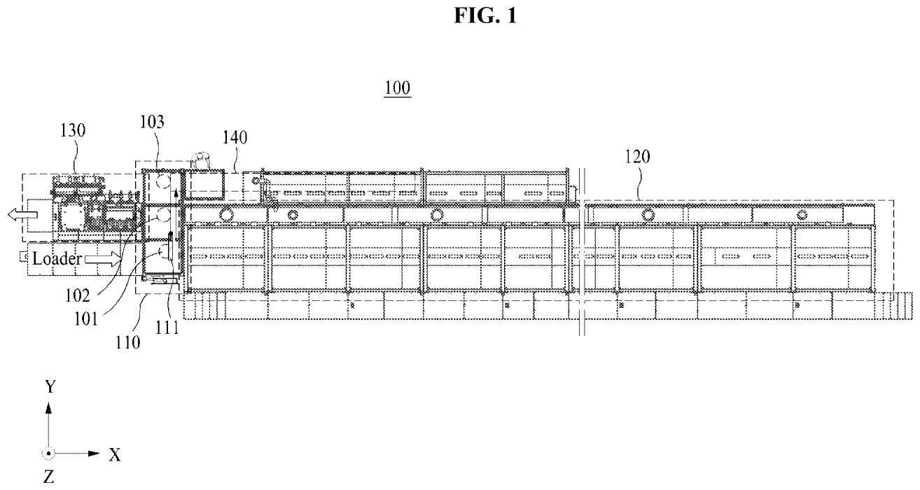

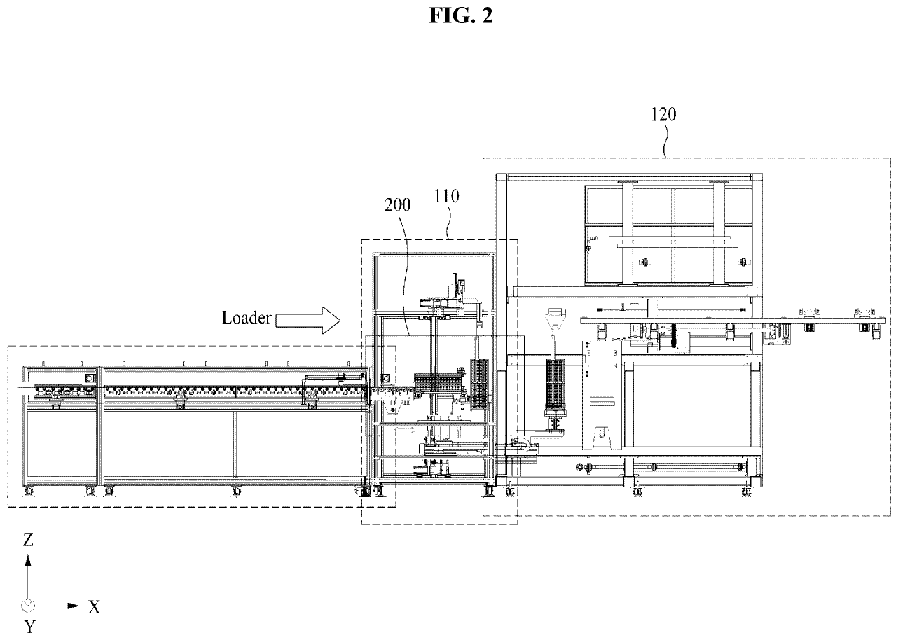

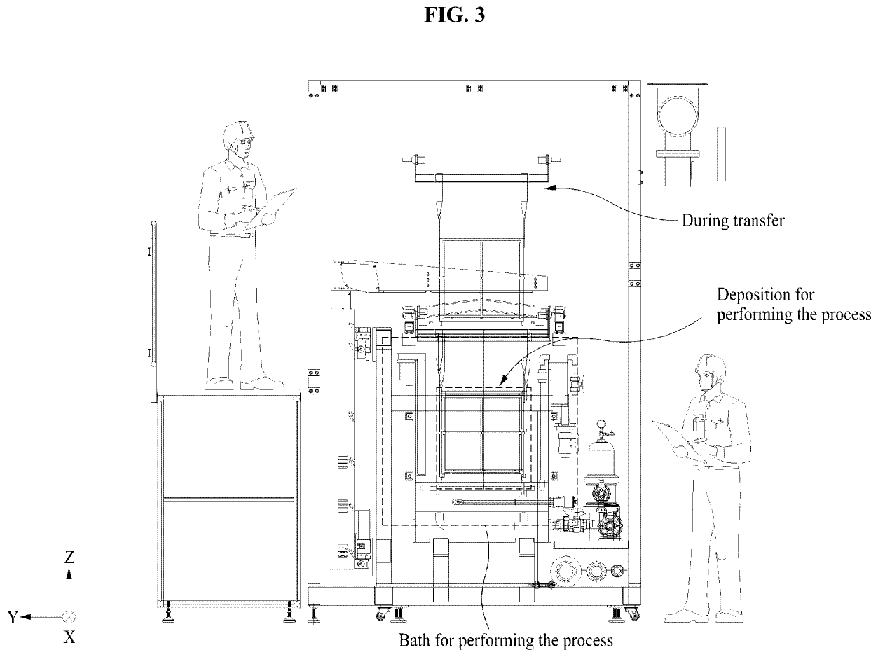

FIGS. 1, 2, and 3 are a planar drawing, a side view, and a front view, respectively, illustrating a process connection device in a substrate manufacturing process according to an embodiment, which automates integration of a vertical process and a horizontal process.

Referring to the drawings, a process connection device 100 in a substrate manufacturing process according to an embodiment includes an automation unit 110 as a device for connecting a vertical process and a horizontal process, and may include a vertical process related equipment 120, a horizontal process related equipment 130, and a buffer 140. Accordingly, the automation unit 110 may connect the vertical process related equipment 120, the horizontal process related equipment 130, and the buffer 140.

The vertical process related equipment 120 means a device for performing a vertical process such as chemical treatment for a carrier 111 on which a plurality of substrates are stacked in vertical position.

Hereinafter, the term “vertical position” means a position in which a flat, wide surface of the substrate or the carrier 111 is included within a predetermined angular range relative to an imaginary plane perpendicular to the ground. For example, the “vertical position” may mean a position in which the flat, wide surface of the substrate or the carrier 111 is included within an angular range of 45 to 135 degrees. The numerical range of angles is merely exemplary, and the angular range defining the “vertical position” may be set in various ways.

Also, hereinafter, the term “substrate” may be not only a substrate based on a semiconductor material, but also a glass substrate itself based on a glass material. That is, the “substrate” stacked on the carrier 111 and subjected to the vertical process and the horizontal process may be a glass package.

The vertical process performed by the vertical process related equipment 120 is a substrate process in a carrier 111 standard, not a substrate standard, in which the vertically positioned carrier 111 may move in a horizontal direction within the vertical process related equipment 120.

Here, the vertical process related equipment 120 may have a structure in which inlet and outlet of the carrier 111 are implemented as a single port at the same location and direction. Accordingly, a vertical process transfer loader and unloader 112 of the automation unit 110, which will be described later, may insert the carrier 111 into the vertical process related equipment 120, and then receive the carrier 111 discharged therefrom after completion of the vertical process.

The horizontal process related equipment 130 means a device for performing a horizontal process such as cleaning and drying for substrates in a horizontal position.

Hereinafter, the term “horizontal position” means a position in which a flat, wide surface of the substrate or the carrier 111 is included within a predetermined angular range relative to an imaginary plane parallel to the ground. For example, the “horizontal position” may mean a position in which the flat, wide surface of the substrate or the carrier 111 is included within an angular range of 0 to 45 degrees or 135 to 180 degrees. The numerical range of angles is merely exemplary, and the angular range defining the “horizontal position” may be set in various ways.

The horizontal process performed by the horizontal process related equipment 130 is a substrate process in a substrate standard, not a carrier 111 standard, in which the horizontally positioned substrate may move in a horizontal direction within the horizontal process related equipment 130.

Such vertical process related equipment 120 and horizontal process related equipment 130 may be devices at different locations in either the same direction or opposing directions in order to minimize the equipment space and improve spatial efficiency. For example, as shown in the drawing, the vertical process related equipment 120 and the horizontal process related equipment 130 may be located on different rows or columns on the same floor, and in opposing directions.

The buffer 140 is a device for temporarily storing the carrier 111 with stacked substrates or the substrate, and may be provided at different locations like the vertical process related equipment 120 and the horizontal process related equipment 130.

The automation unit 110 connects the vertical process related equipment 120 and the horizontal process related equipment 130, which are implemented at different locations, and may support to perform the vertical process and the horizontal process for each substrate by supplying the carrier 111, on which a plurality of substrates are stacked, in a vertical position to the vertical process related equipment 120 and supplying each of the plurality of substrates to the horizontal process related equipment 130.

For this, the automation unit 110 may integrally implement a carrier position conversion function, a movement function between a location of the vertical process related equipment 120 and a location of the horizontal process related equipment 130, and a substrate discharging function from the carrier.

More specifically, the automation unit 110 may be located at a first location 101 of the process connection device 100 in the substrate manufacturing process (the location of the vertical process related equipment 120), and insert the vertically positioned carrier 111 into the vertical process of the vertical process related equipment 120.

Here, the vertically positioned carrier 111 inserted into the vertical process by the automation unit 110 may be provided by inserting the horizontally position carrier 111 with stacked horizontally positioned substrates into the automation unit 110 in a carrier standard and then converting it into the vertical position by the automation unit 110. The conversion the horizontally positioned carrier 111 to the vertical position may be carried out by the automation unit 110 rotating the horizontally positioned carrier 110 by 90 degrees in either a clockwise or counter clockwise direction.

However, this is not intended to be limiting, and the vertically positioned carrier 111 inserted into the vertical process by the automation unit 110 may be inserted into the automation unit 110 in a carrier standard with stacked vertically positioned substrates.

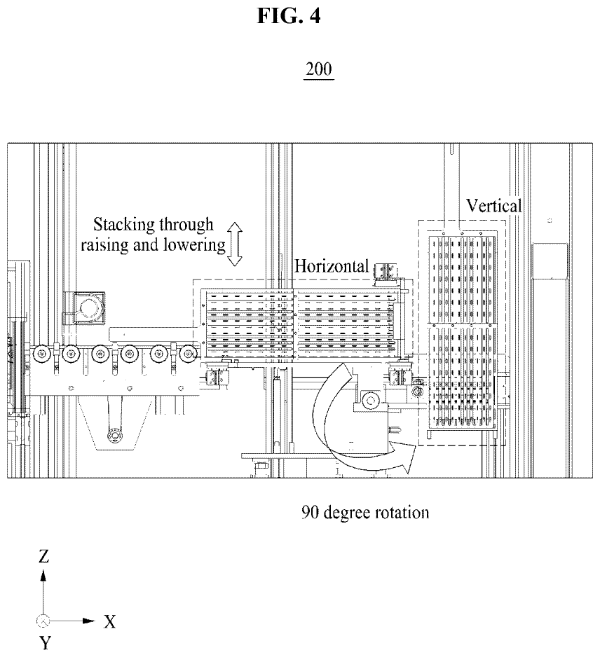

Furthermore, the vertically positioned carrier 111 inserted into the vertical process by the automation unit 110 may be provided by automation unit 110 sequentially stacking the horizontally positioned substrates loaded in a horizontal direction on the horizontally positioned carrier, and converting the horizontally positioned carrier 111 into the vertical position. A more detailed description thereof will be provided with reference to FIG. 4.

Also, similarly, the vertically positioned carrier 111 inserted into the vertical process by the automation unit 110 may be provided by the automation unit 110 sequentially stacking the vertically positioned substrates on the vertically positioned carrier 111 in response to the insert of the vertically positioned substrates.

The inserting the vertically positioned carrier 111 into the vertical process of the vertical process related equipment 120 may be carried out by the vertical process transfer loader and unloader 112.

When the carrier 111 is discharged from the vertical process, the automation unit 110 may move to a second location 102 of the process connection device 100 in the substrate manufacturing process (the location of the horizontal process related equipment 130) while accommodating the vertically positioned carrier 111 discharged from the vertical process (movement function). The automation unit 110 at the second location 102 of the process connection device 100 in the substrate manufacturing process may convert the vertically positioned carrier 111 into the horizontal position (carrier position conversion function), and then sequentially discharge the horizontally positioned substrates from the horizontally positioned carrier 111 to insert them into the horizontal process of the horizontal process related equipment 130 (substrate discharging function from the carrier).

Although the drawings illustrate that as the vertical process related equipment 120 and the horizontal process related equipment 130 are located in different rows or columns on the same floor, the vertical process related equipment 120 and the horizontal process related equipment 130 are connected to each other through horizontal movement of the automation unit 110, it is not limited or restricted thereto. As the vertical process related equipment 120 and the horizontal process related equipment 130 are located on different floors, the vertical process related equipment 120 and the horizontal process related equipment 130 may be connected to each other through vertical movement of the automation unit 110. At this time, the movement of the automation unit 110 may be implemented to allow both horizontal and vertical movement regardless of whether the vertical process related equipment 120 and the horizontal process related equipment 130 are located in different rows or columns on the same floor or different floors.

The converting the vertically positioned carrier 111 into the horizontal position may be performed by the automation unit 110 rotating the vertically positioned carrier 111 by 90 degrees in either a counterclockwise or clockwise direction.

At this time, the automation unit 110 may sequentially discharge the horizontal positioned substrates while raising or lowering the horizontally positioned carrier 111 where the substrates are staked. For example, the automation unit 110 may sequentially discharge the horizontally positioned substrates by adjusting the rising or lowering height by the horizontally positioned carrier 111 according to the thickness of each substrate.

As more particular example, the automation unit 110 may control the height of the carrier 111 such that the uppermost substrate among the substrates stacked on the carrier 111 is located at a height equal to or higher than that of the loader of the horizontal process related equipment 130, and then may discharge the uppermost substrate among the substrates stacked on the carrier 111 to the loader of the horizontal process related equipment 130, and raise the horizontally positioned carrier 111 from which the uppermost substrate is discharged by a height greater than the thickness of the substrate so that the next substrate is located at a height equal to or higher than that of the loader of the horizontal process related equipment 130, thereby discharging the next substrate to the loader of the horizontal process related equipment 130.

As another particular example, the automation unit 110 may control the height of the carrier 111 such that the lowermost substrate among the substrates stacked on the carrier 111 is located at a height equal to or higher than the loader of the horizontal process related equipment 130, and then may discharge the lowermost substrate among the substrates stacked on the carrier 111 to the loader of the horizontal process related equipment 130, and lower the horizontally positioned carrier 111 from which the lowermost substrate is discharged by a height greater than the thickness of the substrate so that the next substrate is located at a height equal to or higher than that of the loader of the horizontal process related equipment 130, thereby discharging the next substrate to the loader of the horizontal process related equipment 130. In this case, partitions for separating and stacking substrates may be formed inside the carrier 111 so that each substrate can be easily discharged.

However, it is not limited thereto, and the automation unit 110 may sequentially discharge the horizontally positioned substrates by moving the horizontally positioned carrier 111, on which the substrates are stacked, in a horizontal direction.

Alternatively, the automation unit 110 may sequentially discharge the horizontal positioned substrates from the horizontally positioned carrier 111 without any specific movement of the horizontally positioned carrier 111 on which the substrates are stacked.

Also, the automation unit 110 may connect not only the vertical process related equipment 120 and the horizontal process related equipment 130 to each other, but also to the buffer 140 in which the carrier 111 with stacked substrates or the substrates are temporarily stored. Therefore, even if a waiting period occurs in the vertical process related equipment 120 or the horizontal process related equipment 130, the automation unit 110 may move to a third location 103 and transfer the carrier 111, on which the substrates are stacked, or the substrate to the buffer 140 for storage, thereby preventing the entire process from being stopped.

The buffer 140 may be located in a different row or column on the same floor for the vertical process related equipment 120 and the horizontal process related equipment 130. Accordingly, when the buffer 140 is located in a different row or column on the same floor for the vertical process related equipment 120 and the horizontal process related equipment 130, the automation unit 110 may connect the buffer 140 to the vertical process related equipment 120 and the horizontal process related equipment 130 through the horizontal movement function. Meanwhile, when the buffer 140 is located on a different floor for the vertical process related equipment 120 and the horizontal process related equipment 130, the automation unit 140 may connect the buffer 140 to the vertical process related equipment 120 and the horizontal process related equipment 130 through the vertical movement function. At this time, the movement of the automation unit 110 may be implemented to allow both horizontal and vertical movement, regardless of whether the vertical process related equipment 120 and the horizontal process related equipment 130 are located in different rows or columns on the same floor or on different floors.

Like this, the automation unit 110 provided in the substrate manufacturing process may achieve technical effects of enhancing productivity and quality of cleaning and drying after chemical treatment of the substrates by automating integration of the vertical process—which performs a substrate process in a standard of the carrier 111 on which substrates are vertically stacked—and a horizontal process—which performs cleaning and drying in a substrate standard for each of the horizontally positioned substrates.

Also, the automation unit 110 provided in the substrate manufacturing process may achieve technical effects of minimizing equipment space and maximizing space efficiency by efficiently connecting the vertical process and the horizontal process, which are implemented at different locations.

FIG. 4, which is a drawing enlarging and illustrating a region 200 including the automation unit 110 in the process connection device 100 according to an embodiment, is a side view for describing a carrier position conversion function of the automation unit 110 and a carrier stacking function of substrates.

Referring to FIG. 4, the automation unit 110 may prepare the vertically positioned carrier 111 to be inserted into the vertical process by sequentially stacking the horizontally positioned substrates loaded in a horizontal direction onto the horizontally positioned carrier, and converting the horizontally positioned carrier 111 into a vertical position.

At this time, the automation unit 110 may lower or raise the horizontal positioned carrier 111, on which the substrates are not stacked, and sequentially stack the horizontally positioned substrates. For example, the automation unit 110 may sequentially stack the horizontally positioned substrates by adjusting the lowering and rising height by the horizontally positioned carrier 111 according to the thickness of each substrate.

As more particular example, the automation unit 110 may locate the horizontally positioned carrier 111 at a height equal to or lower than that of the loader to stack a first loaded substrate, and locate the horizontally positioned carrier 111 with the first substrate stacked thereon at a height equal to or lower than that of the loader by lowering the horizontally positioned carrier 111 with the first substrate stacked thereon by a depth greater than the thickness of the substrate to stack a second loaded substrate.

As another particular example, the automation unit 110 may locate the lowermost substrate stacking space among substrate stacking spaces formed by partitions inside the horizontally positioned carrier 111 at a height equal to or lower than that of the loader to stack a first loaded substrate, and locate the next substrate stacking space located above the lowermost substrate stacking space at a height equal to or lower than that of the loader by raising the horizontally positioned carrier 111 with the first substrate stacked thereon by a depth greater than the thickness of the substrate to stack a second loaded substrate. In this case, partitions for separating and stacking substrates may be formed inside the carrier 111.

However, it is not limited thereto, and the automation unit 110 may sequentially stack the horizontally positioned substrates by moving the horizontally positioned carrier 111, on which the substrates are not stacked, in a horizontal direction.

Alternatively, the automation unit 110 may sequentially stack the horizontal positioned substrates on the horizontally positioned carrier 111 without any specific movement of the horizontally positioned carrier 111 on which the substrates are not stacked.

The converting the horizontally positioned carrier 111 into a vertical position may be carried out by the automation unit 110 rotating the horizontally positioned carrier 111 by 90 degrees in a clockwise or counter clockwise direction as shown in the drawing.

The inserting the vertically positioned carrier 111 into the vertical process of the vertical process related equipment 120 may be carried out by the above described vertical process transfer loader and unloader 112.

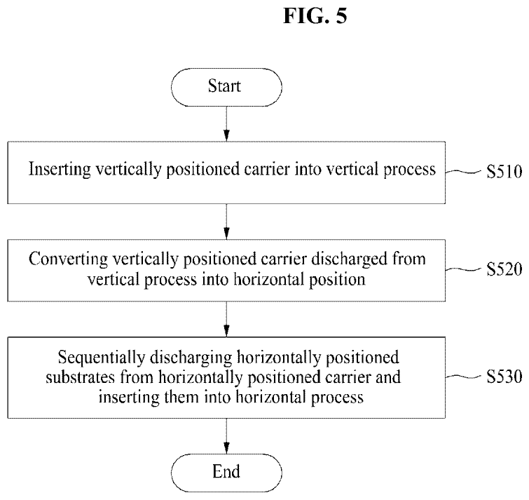

FIG. 5 is a flow chart illustrating an operating method of a process connection device in a substrate manufacturing process shown in FIGS. 1 to 4.

The following description of an operating method of the process connection device 100 in a substrate manufacturing process is based on premise that the method is performed by the above described automation unit 110 included in the process connection device 100 in the substrate manufacturing process.

In step S510, the automation unit 110 may insert the vertically positioned carrier 111 into a vertical process.

In step S510, the vertically positioned carrier 111 inserted into the vertical process by the automation unit 110 may be inserted into the automation unit 110 in a carrier standard with stacked vertically positioned substrates.

Alternatively, in step S510, the vertically positioned carrier 111 inserted into the vertical process by the automation unit 110 may be one that is provided by inserting the horizontally positioned carrier 111, on which the horizontally positioned substrates are stacked, into the automation unit 110 in a carrier standard, and then converting the horizontally positioned carrier 111 into a vertical position by the automation unit 110. The converting the horizontally positioned carrier 111 into a vertical position may be performed by rotating the horizontally positioned carrier 111 by 90 degrees in either a clockwise or counterclockwise direction by the automation unit 110.

Alternatively, in step S510, the vertically positioned carrier 111 inserted into the vertical process by the automation unit 110 may be one that is provided by the automation unit 110 sequentially stacking the horizontally positioned substrates loaded in a horizontal direction onto the horizontally positioned carrier and converting the horizontally positioned carrier 111 into a vertical position.

Alternatively, in step S510, the vertically positioned carrier 111 inserted into the vertical process by the automation unit 110 may be one that is provided by the automation unit 110 sequentially stacking the vertically positioned substrates onto the vertically positioned carrier 111 in response to the inserting the vertically positioned substrates.

In step S520, the automation unit 110 may convert the vertically positioned carrier 111 discharged from the vertical process into the horizontal position based on a carrier position conversion function.

More particularly, in step S520, the automation unit 110 may move from a location of the vertical process related equipment 120 to a location of the horizontal process related equipment 130, and then convert the vertically positioned carrier 111 into a horizontal position.

In step S530, the automation unit 110 may sequentially discharge the horizontally positioned substrates from the horizontally positioned carrier 111 and inserting them into a horizontal process. More particularly, the automation unit 110 may raise the horizontally positioned carrier 111 with stacked substrates and sequentially discharge the horizontally positioned substrates. For example, the automation unit 110 may sequentially discharge the horizontally positioned substrates by adjusting the rising or lowering height of the horizontally positioned carrier 111 according to a thickness of each substrate.

As such, in steps S510 to S530, the automation unit 110 may integrate and connect a vertical process which is a substrate process in a standard of the carrier 111 with vertically positioned substrates stacked thereon and a horizontal process for performing cleaning and drying in a substrate standard for each of horizontally positioned substrates.

That is, in steps S510 to S530, the automation unit 110 may connect the vertical process and the horizontal process to each other, which are implemented at different locations, based on the movement function.

In addition, although not illustrated as a separate step, the automation unit 110 may move and transfer the carrier 111 or the substrates to the buffer 140 temporarily storing the carrier 140 with stacked substrates or the substrates. For example, the automation unit 110 may not only connect the vertical process related equipment 120 and the horizontal process related equipment 130 to each other, but also connect to the buffer 140 in which the carrier 111 with stacked substrates or the substrates are temporarily stored. In this way, even if a waiting period occurs in the vertical process related equipment 120 or the horizontal process related equipment 130, the automation unit 110 may transfer the carrier 111 with stacked substrates or the substrates to the buffer 140 for storage.

As described above, although the embodiments have been described in connection with the limited embodiments and the drawings, those skilled in the art may modify and change the embodiments in various ways from the description. For example, proper results may be achieved although the aforementioned descriptions are performed in order different from that of the described method and/or the aforementioned components, such as a system, a structure, a device, and a circuit, are coupled or combined in a form different from that of the described method or replaced or substituted with other components or equivalents thereof.

Accordingly, other implementations, other embodiments, and the equivalents of the claims fall within the scope of the claims.

### DESCRIPTION OF REFERENCE NUMERALS

100: Process connection device in a substrate manufacturing process
110: Automation unit
111: Carrier
112: Vertical process transfer loader and unloader
120: Vertical process related equipment
130: Horizontal process related equipment
140: Buffer

What is claimed is:

1. A process connection device in a substrate manufacturing process, comprising an automation unit configured to sequentially stack horizontally positioned substrates loaded in a horizontal direction onto a horizontally positioned carrier, convert the horizontally positioned carrier into a vertical position, insert the vertically positioned carrier into a vertical process, convert the vertically positioned carrier discharged from the vertical process into a horizontal position, and sequentially discharge the horizontally positioned substrates from the horizontally positioned carrier and insert them into a horizontal process.

2. The process connection device in a substrate manufacturing process of claim 1, wherein the automation unit is configured to integrally implement a carrier stacking function of substrates, a carrier position conversion function, a movement function between a location of the vertical process related equipment and a location of the horizontal process related equipment, and a substrate discharging function from the carrier.

3. The process connection device in a substrate manufacturing process of claim 2, wherein the automation unit is configured to connect the vertical process and the horizontal process, which are implemented at different locations, through the movement function.

4. The process connection device in a substrate manufacturing process of claim 3, wherein the vertical process includes a carrier standard substrate process, and
the horizontal process includes a substrate standard substrate process.

5. The process connection device in a substrate manufacturing process of claim 1, wherein the automation unit is configured to move from a location of the vertical process related equipment to a location of the horizontal process related equipment and then convert the vertically positioned carrier into a horizontal position.

6. The process connection device in a substrate manufacturing process of claim 5, wherein the vertical process related equipment and the horizontal process related equipment are provided at different locations in either the same direction or opposing directions.

7. The process connection device in a substrate manufacturing process of claim of claim 1, wherein the automation unit is configured to lower or raise the horizontally positioned carrier where the substrates are not stacked while sequentially stacking the horizontally positioned substrates, and raise or lower the horizontally positioned carrier where the substrates are stacked while sequentially discharging the horizontally positioned substrates.

8. The process connection device in a substrate manufacturing process of claim 7, wherein the automation unit is configured to adjust the rising or lowering height of the horizontally positioned carrier according to a thickness of each substrate.

9. The process connection device in a substrate manufacturing process of claim 1, wherein the automation unit is configured to transfer the carrier with stacked substrates to a buffer for temporary storage.

10. An operating method of a process connection device in a substrate manufacturing process, comprising:
sequentially stacking horizontally positioned substrates loaded in a horizontal direction onto a horizontal positioned carrier, by an automation unit included in the process connection device;
converting the horizontally positioned carrier into a vertical position, by the automation unit;
inserting the vertically positioned carrier into a vertical process, by the automation unit;
converting the vertically positioned carrier discharged from the vertical process into a horizontal position, by the automation unit; and
sequentially discharging the horizontally positioned substrates from the horizontally positioned carrier and inserting them into a horizontal process, by the automation unit.

11. The operating method of a process connection device in a substrate manufacturing process of claim 10, wherein the converting the vertically positioned carrier discharged from the vertical process into a horizontal position is moving the automation unit from a location of the vertical process related equipment to a location of the horizontal process related equipment, and then converting the vertically positioned carrier to a horizontal position.

12. The operating method of a process connection device in a substrate manufacturing process of claim 11, wherein the vertical process and the horizontal process, which are implemented at different locations, are connected to each other through a movement of the automation unit.

13. The operating method of a process connection device in a substrate manufacturing process of claim 12, wherein the vertical process includes a carrier standard substrate process, and
the horizontal process includes a substrate standard substrate process.

14. The operating method of a process connection device in a substrate manufacturing process of claim 10, wherein the sequentially stacking horizontally positioned substrates loaded in a horizontal direction onto a horizontal positioned carrier comprises lowering or raising the horizontally positioned carrier where the substrates are not stacked while sequentially stacking the horizontally positioned substrates,
the sequentially discharging the horizontally positioned substrates from the horizontal positioned carrier and inserting them into a horizontal process comprises raising or lowering the horizontally positioned carrier where the substrates are stacked while sequentially discharging the horizontally positioned substrates.

15. The operating method of a process connection device in a substrate manufacturing process of claim 10, further comprising transferring the carrier with stacked substrates to a buffer for temporary storage, by the automation unit.
